(19) United States
(12) Patent Application Publication
(10) Pub. No.: US 2017/0288057 A1
(43) Pub. Date: Oct. 5, 2017

(54) KITE SHAPED CAVITY FOR EMBEDDING MATERIAL

(71) Applicant: Shanghai Huali Microelectronics Corporation, Shanghai (CN)

(72) Inventor: Jianhua Zhou, Shanghai (CN)

(21) Appl. No.: 15/131,021

(22) Filed: Apr. 17, 2016

(30) Foreign Application Priority Data
Mar. 30, 2016 (CN) 201610192733.9

(51) Int. Cl. H01L 29/78; H01L 29/06; H01L 29/66; H01L 29/04; H01L 21/02

(52) U.S. Cl. CPC H01L 29/7833; H01L 29/045; H01L 21/02529; H01L 21/02532; H01L 29/6656; H01L 29/0649

(57) ABSTRACT

The present invention is directed to semiconductor processes and devices. More specifically, embodiments of the present invention provide a semiconductor device that comprises a kite-shaped cavity, and the shaped cavity is filled with silicon and germanium material. There are other embodiments as well.

### CROSS-REFERENCES TO RELATED APPLICATIONS

The present application claims priority to Chinese Patent Application No. 201610192733.9, filed on Mar. 30, 2016, entitled “KITE SHAPED CAVITY FOR SIGE FILLING MATERIAL”, which is incorporated by reference herein for all purposes.

### BACKGROUND OF THE INVENTION

The present invention is directed to semiconductor processes and devices.

Since the early days when Dr. Jack Kilby, at Texas Instruments, invented the integrated circuit, scientists and engineers have made numerous inventions and improvements on semiconductor devices and processes. The last five decades or so have seen a significant reduction in semiconductor sizes, which translate to ever increasing processing speed and decreasing power consumption. So far, the development of semiconductor has generally followed Moore's Law, which roughly states that the number of transistors in a dense integrated circuit doubles approximately every two years. Now, semiconductor processes are pushing toward below 20 nm, a situation in which some companies are now working on 14 nm processes. Just to provide a reference, a silicon atom is about 0.2 nm, which means the distance between two discrete components manufactured by a 20 nm process is just about a hundred silicon atoms.

Manufacturing semiconductor devices has thus become more and more challenging and is pushing toward the boundary of what is physically possible. Huali Microeletronic Corporation™ is one of the leading semiconductor fabrication companies that has focused on the research and development of semiconductor devices and processes.

One of the recent developments in semiconductor technologies has been utilization of silicon germanium (SiGe) in semiconductor manufacturing. For example, SiGe can be used for manufacturing of complementary metal-oxide-semiconductor (CMOS) with adjustable band gap. While conventional techniques exist for SiGe-based processes, these techniques are unfortunately inadequate for the reasons provided below. Therefore, improved methods and systems are desired.

### BRIEF DESCRIPTION OF THE DRAWINGS

FIG. 1 is a simplified diagram illustrating a conventional U-shaped cavity for SiGe material.

FIG. 2 is a simplified diagram illustrating a semiconductor device with Σ-shaped SiGe embedding.

FIGS. 3A-M are simplified diagrams illustrating a process for providing a kite-shaped cavity according to an embodiment of the present invention.

FIG. 4 is a simplified diagram illustrating a semiconductor device with a T-shaped trench according to an embodiment of the present invention.

FIG. 5 is a simplified diagram illustrating a semiconductor device 500 having a kite-shaped embedding according to an embodiment of the present invention.

FIGS. 6A-D are simplified diagrams illustrating kite-shaped cavities according to embodiments of the present invention.

### DETAILED DESCRIPTION OF THE INVENTION

The present invention is directed to semiconductor processes and devices. More specifically, embodiments of the present invention provide a semiconductor device that comprises a kite-shaped cavity, and the shaped cavity is filled with silicon and germanium material. There are other embodiments as well.

The following description is presented to enable one of ordinary skill in the art to make and use the invention and to incorporate it in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

Please note, if used, the labels left, right, front, back, top, bottom, forward, reverse, clockwise and counter clockwise have been used for convenience purposes only and are not intended to imply any particular fixed direction. Instead, they are used to reflect relative locations and/or directions between various portions of an object.

As mentioned above, there are many challenges as semiconductor processes scale down. Downscaling IC provides many advantages, including reduction in power consumption and increase in computation speed, as electrons travel less distance from one IC component to another. For example, for CMOS devices, as the sizes of various critical dimensions (e.g., size of gate oxide) decrease, the carrier mobility drops quickly, which adversely affects device performance. For example, silicon substrates are often embedded with other types of material to improve device performance. When silicon germanium type of material is embedded into silicon substrate, since silicon germanium material typically has a lower lattice constant than silicon material, the silicon germanium material typically absorbs pressure from silicon material, which translates to pressure received from trenches. On the other hand, when silicon carbide material is embedded, since silicon carbide material typically has a higher lattice constant than silicon material, silicon carbide material exerts pressure to the silicon substrate and the trenches therein. Uneven pressures due to heterogeneous lattice configuration between a silicon substrate and the embedded material (e.g., SiC or SiGe) are often an important consideration in the geometry of cavity geometry for the embedded material. SiGe technology, when utilized in various applications, can improve device performance by improving carrier mobility.

For certain types of devices and manufacturing processes thereof, SiGe technology can significantly improve device performance. For example, Intel™ explored the usage of SiGe when using a 90 nm process to improve the performance of logic units. As the manufacturing processes moved to 45 nm, 32 nm, and 22 nm, the amount of germanium content increased. In the early SiGe devices, germanium makes up less than 15% of the device. As device size decreases, the amount of germanium increases to 40% or even higher. For example, in a CMOS device, SiGe material is embedded in the source and drain regions. In the past, to increase the amount of embedding of SiGe material, U-shaped and Σ-shaped cavities (or sometimes referred to as recesses) have been proposed for embedding the SiGe materials. Similarly, various types of SiC material also boost device performance by improving carrier mobility. Additionally, SiC may provide improvement on thermal conductivity and/or other characteristics.

As an example, SiGe technology refers to semiconductor devices and processes that utilize SiGe material to improve device performance. For example, SiGe can be used in the heterojunction bipolar transistor (HBT) that offers advantages over both conventional silicon bipolar and silicon CMOS for implementation of communications circuits. Among other features, the use of Ge material in these devices improves device performance. However, SiGe devices and processes have their challenges. Among other things, there are difficulties in growing lattice-matched SiGe alloy on Si. Uniformly growing SiGe at the Si-STI interface is desirable, as it increases the performance of the CMOS device. For example, SiGe processes for manufacturing CMOS and other types of devices may comprise various detention of logic gate patterning, such as 45/40 nm, 32/28 nm, and <22 nm, and it is important to maintain logic gate patterns and geometries.

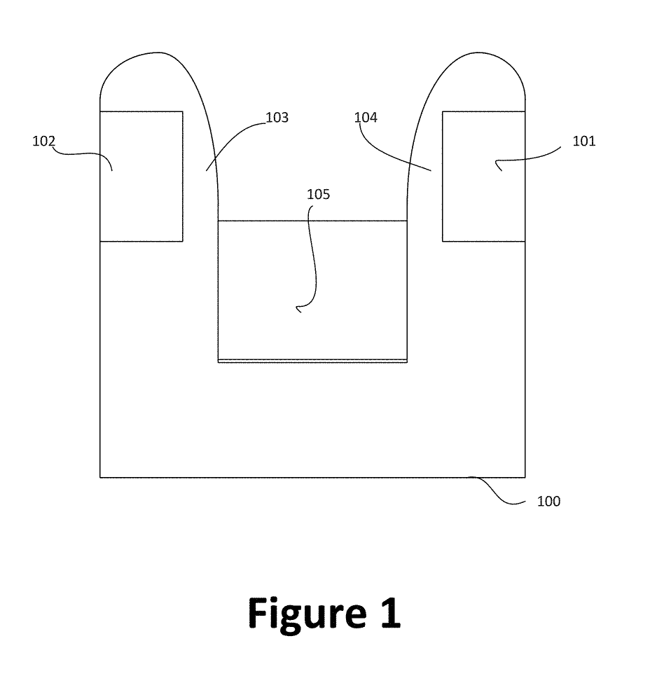

FIG. 1 is a simplified diagram illustrating a conventional U-shaped cavity for SiGe material. A semiconductor substrate 100 comprises a U-shaped cavity for accommodating the filling material 105. For example, the substrate 100 comprises substantially single silicon material. The filling material 105 comprises silicon germanium material. As explained above, with germanium material added to silicon material, carrier mobility and other electrical performance characteristics are improved. For example, the filling material 105 is later used for forming a CMOS device. The semiconductor substrate 100 additionally includes gate materials 101 and 102. For example, the gate materials include metal gate material and/or polysilicon gate material. The gate materials 101 and 102 are protected, respectively, by spacers 103 and 104.

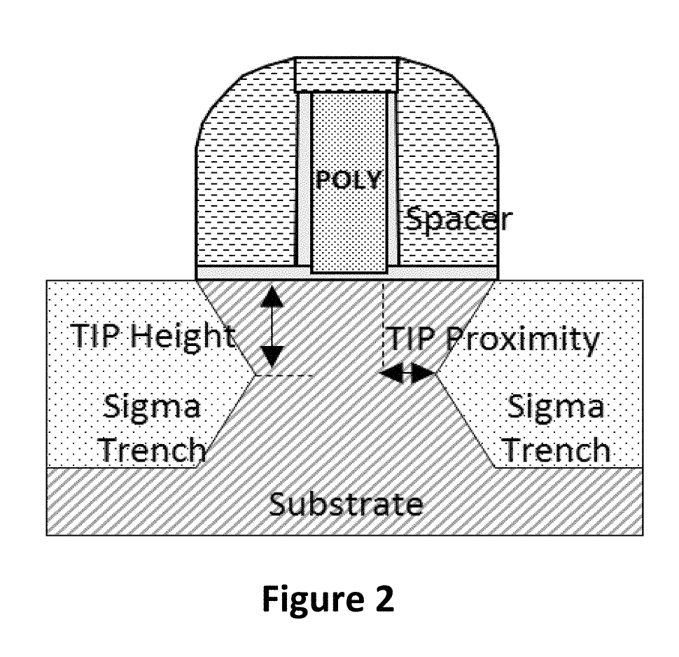

FIG. 2 is a simplified diagram illustrating a semiconductor device with Σ-shaped SiGe embedding. To form Σ-shaped SiGe embedding, a U shaped cavity is formed first, and a wet etching process is performed to remove portions of sidewalls from the U-shaped cavities. The convex shaped cavity provides more volume to accommodate the SiGe material. As shown in FIG. 2, the tip of the Σ-shaped cavity is located near the top surface of the silicon substrate. For example, the term “tip” refers to the convex region of the cavity that horizontally extends from the sidewall of the cavity into the silicon substrate. Typically, tips of the a Σ-shaped cavity are formed by a wet etching process. It is to be appreciated that the tip location and the depth of the Σ-shaped cavity are related. If the initial U-shaped cavity is deep, the tip location is deep and near the bottom of the U-shaped cavity. On the other hand, if the U-shaped cavity is shallow, the tip location is shallow since the bottom of the U-shaped cavity is shallow. This is because, when the wet etching process is performed, the wet etchant etches at all directions of the silicon substrate, starting from the bottom of the U-shaped cavity. It is to be appreciated that for devices with Σ-shaped cavities, performance improvement (e.g., carrier mobility) over conventional devices is largely related to the volume of SiGe material embedded into the cavity and the tip location. More specifically, performance is improved by increasing the amount of embedded SiGe material and placing the tip region close to the device surface (i.e., gate of CMOS devices). Unfortunately, it is difficult for a Σ-shaped cavity to provide both. To increase cavity volume, the initial U-shaped cavity needs to bedeeper. Furthermore, for a deep U-shaped cavity, the Σ-shaped cavity formed thereafter has its tips close to the bottom of the cavity and far away from the device surface. Thus, designing devices with a Σ-shaped cavity often requires balancing between cavity volume and tip proximity to the surface. In various applications, a Σ-shaped cavity is also used for embedding SiC material.

It is to be appreciated that embodiments of the present invention provide a novel kite-shape cavity for embedding SiGe and/or SiC material. The kite-shaped cavity provides both large cavity volume and tip proximity. More specifically, the tips of a kite-shaped cavity are placed substantially near the surface of the silicon substrate, and the tip location is substantially not moved with an increase in cavity depth.

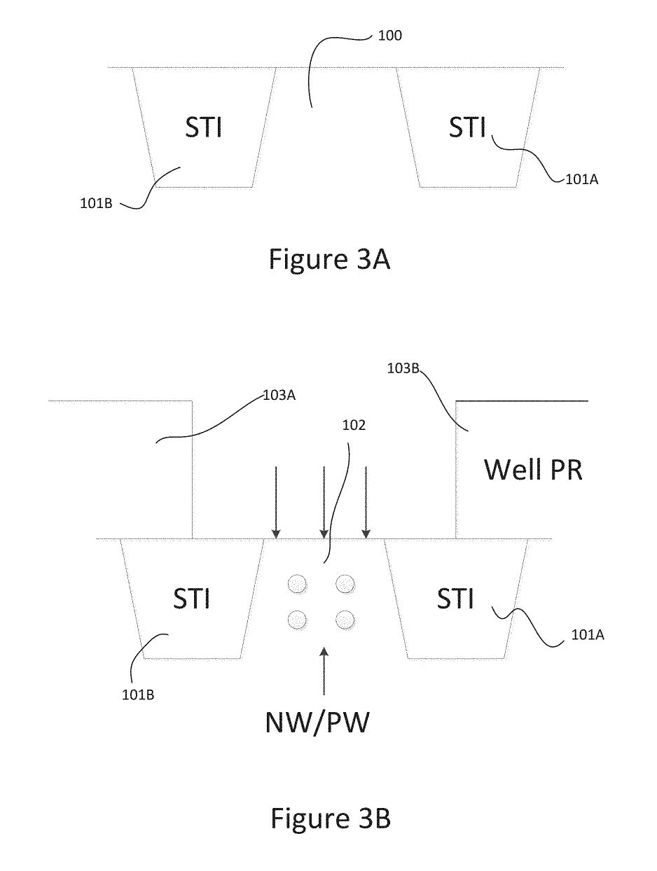

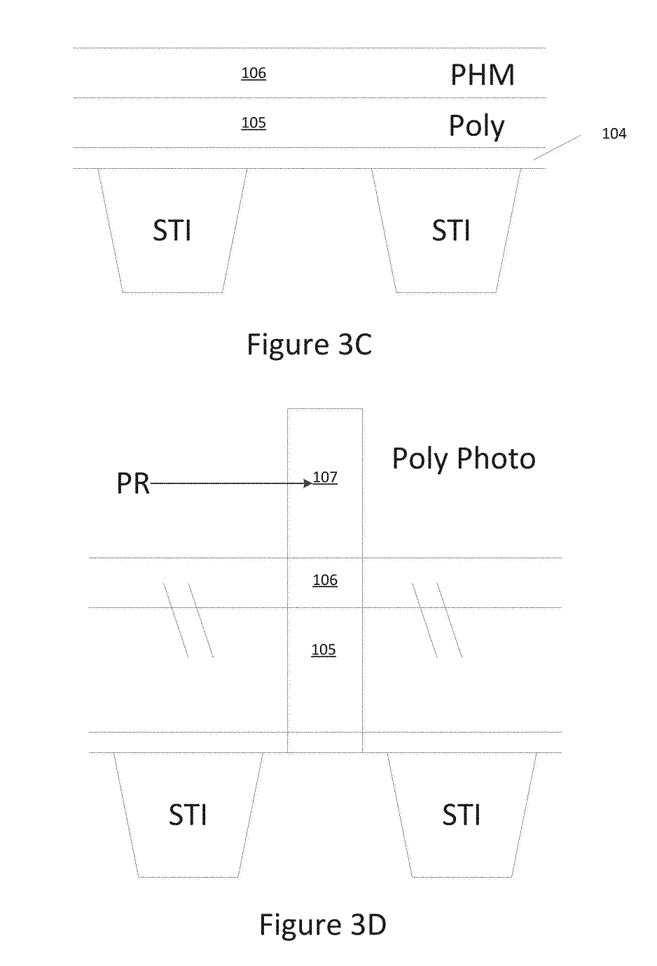

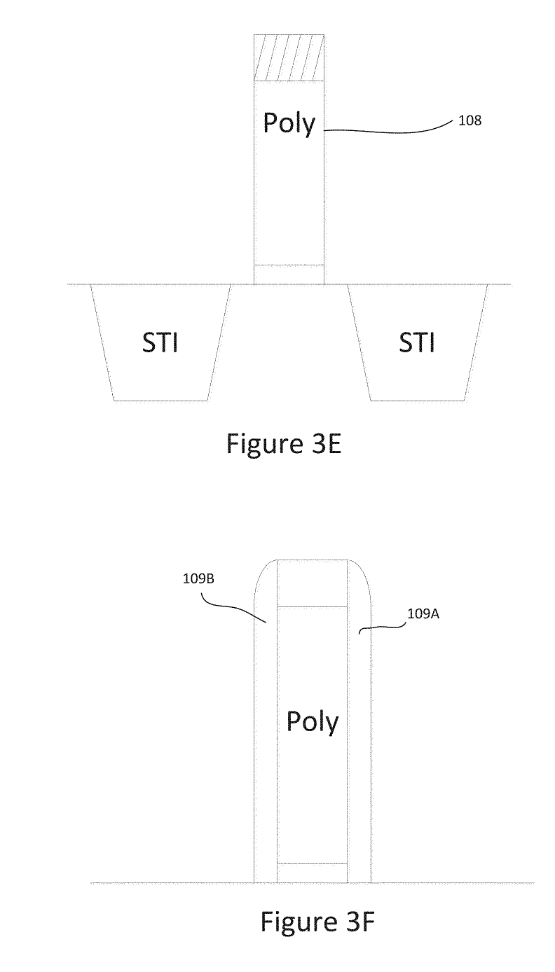

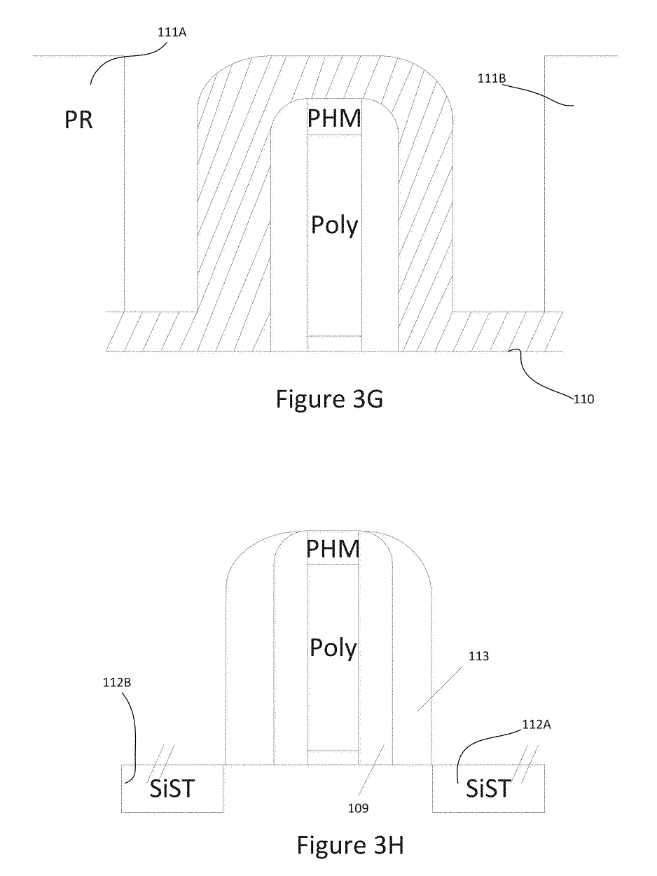

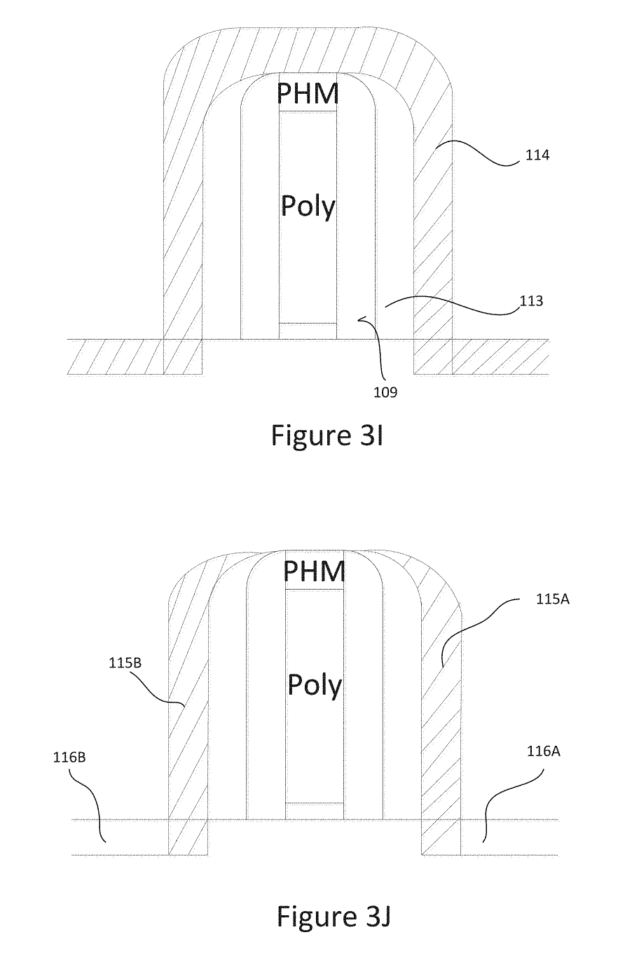

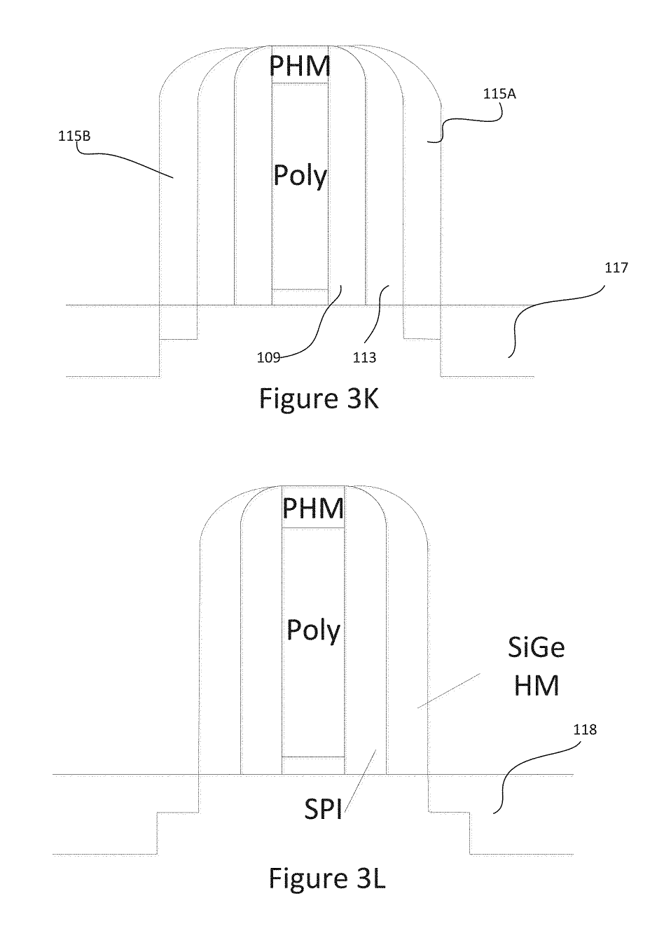

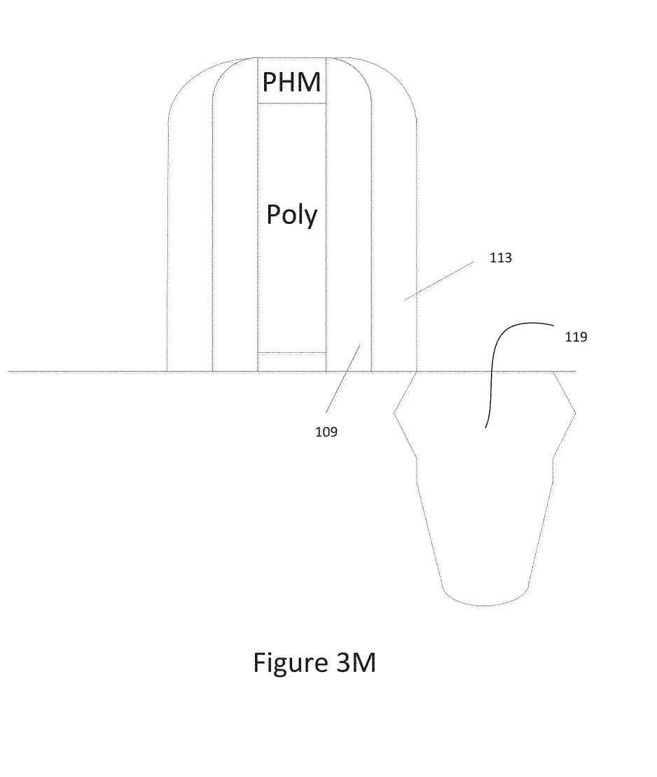

FIGS. 3A-M are simplified diagrams illustrating a process for providing a kite-shaped cavity according to an embodiment of the present invention. These diagrams merely provide an example, which should not unduly limit the scope of the claims. One of ordinary skill in the art would recognize many variations, alternatives, and modifications. Depending on the implementation, one or more steps may be added, removed, repeated, re-arranged, modified, replaced, and/or overlapped, and should not affect cope of the claims. As shown in FIG. 3A, shallow trench isolations (STI) 101A and 101B are formed on the silicon substrate 100. For example, the STIs are formed to provide isolation between adjacent semiconductor device components. Depending on the implementation, the STIs can be formed in various ways, which usually involve etching lithography and etching processes. For example, a directional dry etching process is performed and gaseous species in plasma form are used. In various embodiments, STIs comprise oxide and/or other dielectric materials. A doped-well region 102 is formed between STIs 101A and 10B. Depending on the implementation, the doped-region 102 may be p-well or n-well. For example, the doped region 102 is formed by an ion implantation process, where dopant is bombarded onto the surface of the device surface and penetrates into the doped-region 102. Well photoresists 103A and 103B shields selected regions of the devices from the ion implantation process.

A thin-oxide layer (GOX) 104 is then formed over the semiconductor device, as shown in FIG. 3C. A poly layer 105 is formed over the GOX 104, and the PHM layer overlays the poly layer 105. For example, layers 104-106 may be formed using various deposition methods. Next, a photoresist 107 is formed and overlays a region of the PHM layer 106, as shown in FIG. 3D. A selective etching process is formed, except the region protected by the photoresist 107, and non-covered regions of layers 104-106 are removed. A partially formed gate region 108 is formed, as shown in FIG. 3E. The gate region 108 comprises a GOX layer, a poly layer overlaying the GOX layer, and a PHM layer overlaying the poly layer. Next, sidewalls 109A and 109B are formed, as shown in FIG. 3F. For example, the sidewalls 109A and 109B are formed by deposition, etching, and implantation processes. The sidewalls 109A and 109B are provided as lightly doped drains (LDD). For example, sidewalls 109A and 109B are later used a part of a drain region of a CMOS device. A hard mask layer 110 is then formed, overlaying both the partially formed gate structure and the device surface, as shown in FIG. 3G. Photoresists 111A and 111B are provided at their respective locations as shown. For example, the hard mark layer 110 comprises silicon nitride (SiN) material that is used for processing SiGe or SiC material. The photoresists 111A and 111B are used to provide a mask layer during a selective etching process, where the etchant removes portions of the hard mask 110 and forms silicon shallow trenches 112A and 112B, as shown in FIG. 3H. For example, a directional dry etching process can be used to form the shallow trenches 112A and 112B. For example, a plasma containing gaseous species are used as etchant during the dry etching process. As can be seen in FIG. 3H, the sidewall 109 remains. Also, the hard mask region 113 of the hard mask 110 that is not removed during the etching process is positioned outside the sidewall 110.

Next, an oxide layer 114 is formed, as shown in FIG. 31, overlaying both the gate structure and the trenches 112A and 112B formed earlier. For example, the oxide layer 114 is formed by a deposition process. The oxide layer 114 overlays the hard mask region 113 and is later processed to form offset spacers, which are explained below. The sidewall 109 and the hard mask region 113 are enclosed by the oxide layer 114. Regions 116A and 116B are then formed by removing corresponding regions of the oxide layer 114. Spacers 115A and 115B (formerly parts of the oxide layer 114) are formed, as shown in FIG. 3J. It is to be appreciated that the size of the spacers 115A and 115B are predefined and is used to define the dimension of the kite-shaped cavity that is to be formed. For example, wide spacers produce a narrow deep trench, as the deep trench is formed by etching the region between the two spacers.

A directional etching process is performed to form a deep trench 117, as shown in FIG. 3K. As can be seen in FIG. 3K, the deep trench 117 is aligned by the spacer 115A. Spacers 115A and 115B are then removed, as shown in FIG. 3L. After spacers 115A and 115B are removed, cavity 118 is formed, as shown in FIG. 3L. Cavity 118 is shown with a T-shape, which is a combination of deep trench 117 shown in FIG. 3K and the shallow trench 112A. A wet etching process is then performed to form the kite-shaped cavity 119 as shown in FIG. 3M. For example, tetramethylammonium hydroxide (TMAH) material is used as the etchant in the wet etching process. Depending on the implementation, other types of wet etchants may be used as well. As can be seen in FIG. 3M, the tip location and geometry of the kite-shaped cavity 119 are based on the location and size of the shallow trench 112A, as TMAH material tends to etch into silicon material that it comes to contact with. The depth of the kite-shaped cavity 119 is mostly based on the depth of the deep trench 117.

Depending on the implementation, SiGe and/or SiC material is embedded into the kite-shaped cavity 119. It is to be appreciated that devices with kite-shaped embedding can have better performance than U-shaped embedding and sigma-shaped embedding. More specifically, by having the tip of the cavity positioned near the gate region where the channels are later formed when operating, effect of SiGe and/or SiC embedding on performance gain is more prominent. Additionally, since tip location and embedding volume (e.g., embedding depth) are substantially independent for kite-shaped cavity, kite-shaped embedding can have a large volume and depth while the tip regions stay near the gate structures. Depending on the specific implementation, kite-shaped embedding can provide measurable performance can in conductivity. For example, a CMOS device with kite-shaped SiGe and/or SiC embedding can provide a 5-10% increase in conductivity compared to conventionally shaped (e.g., U-shaped or sigma-shaped) embeddings.

FIG. 4 is a simplified diagram illustrating a semiconductor device with a T-shaped trench according to an embodiment of the present invention. This diagram is merely an example, which should not unduly limit the scope of the claims. One of ordinary skill in the art would recognize many variations, alternatives, and modifications. As an example, the semiconductor device is manufactured according to processes illustrated in FIGS. 3A-M. As can be seen in FIG. 4, the device includes a T-shaped trench in the silicon substrate.

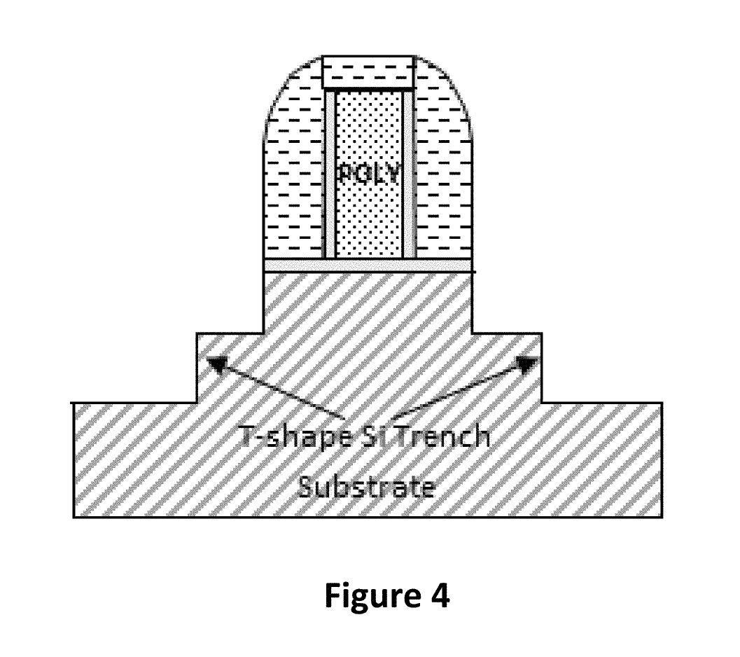

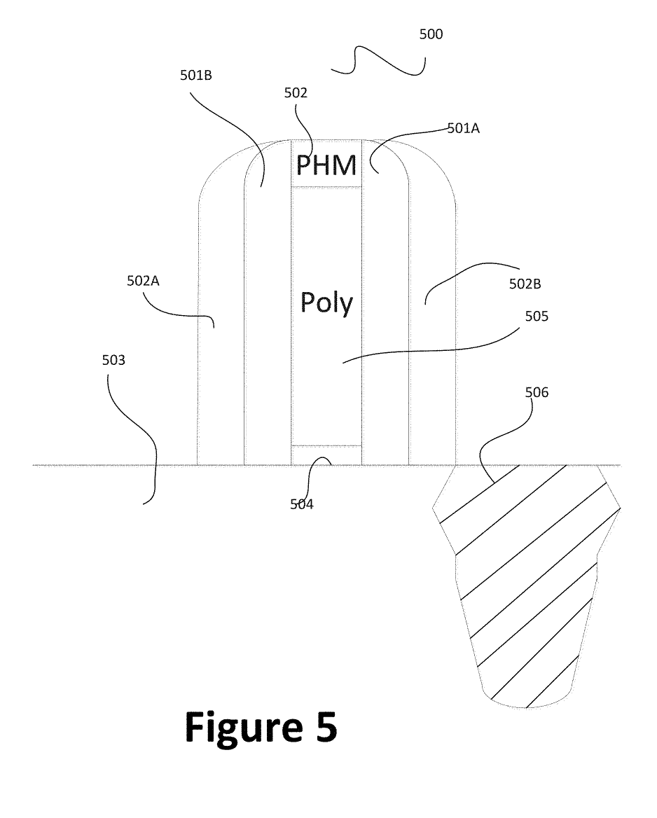

FIG. 5 is a simplified diagram illustrating a semiconductor device 500 having a kite-shaped embedding according to an embodiment of the present invention. This diagram is merely an example, which should not unduly limit the scope of the claims. One of ordinary skill in the art would recognize many variations, alternatives, and modifications. As shown in FIG. 5, device 500 comprises a silicon substrate 504. A gate structure overlays a surface region of the substrate 504. The gate structure includes a GOX layer 504, a polysilicon region 505, a PHM region 502, sidewalls 501A and 501B, and hard masks 502A and 502B. A kite-shaped embedding 506 is positioned within the kite-shaped cavity in the silicon substrate 504. For example, the embedding 506 may include SiGe and/or SiC material. The tip of the kite-shaped cavity comprises angled sidewalls. For example, angled sidewalls are characterized by a (1 1 1) lattice plane or an angle of about 57.1 degrees. The bottom portion of the kite-shaped cavity also includes an angled wall, which is attributed to the wet etching process.

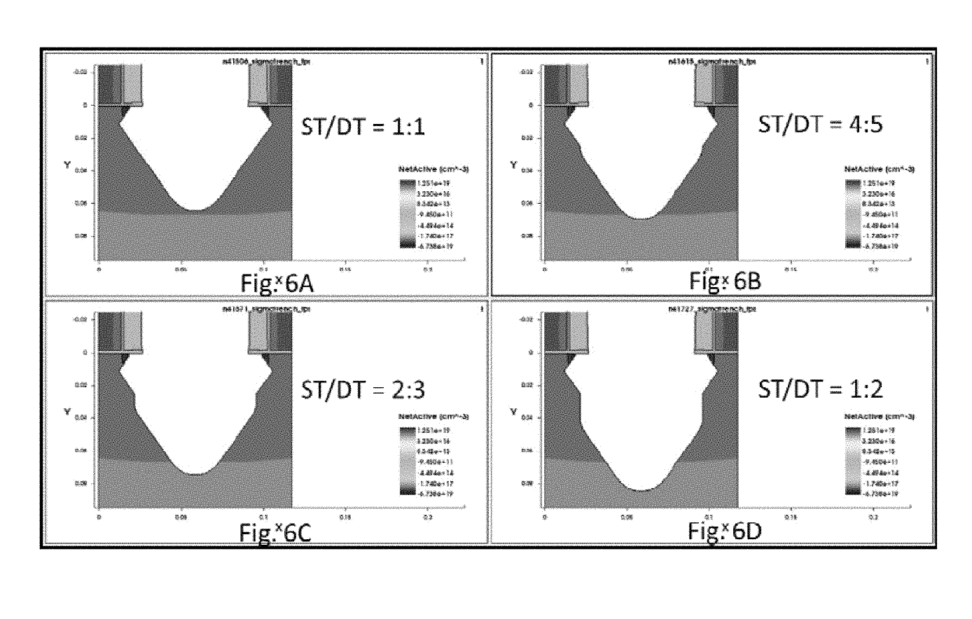

FIGS. 6A-D are simplified diagrams illustrating kite-shaped cavities according to embodiments of the present invention. These diagrams merely provide an example, which should not unduly limit the scope of the claims. One of ordinary skill in the art would recognize many variations, alternatives, and modifications. As explained above, embodiments of the present invention provide a kite-shape cavity that is characterized by high depth and close tip proximity to the gate structure. Depending on the implementation, different ratios between shallow trench height and deep trench height can be used. FIG. 6A shows a ratio of 1:1 between the shallow trench and the deep trench (e.g., shallow trench 112A and deep trench 117). FIG. 6B shows a ratio of 4:5 between the shallow trench and the deep trench. FIG. 6C shows a ratio of 2:3 between the shallow trench and the deep trench. FIG. 6D shows a ratio of 1:2 between the shallow trench and the deep trench. As the ratio goes up, from 1:1 to 1:2, the depth of the kite-shape cavity increases, but the tip location remains substantially the same.

According to an embodiment, the present invention provides a semiconductor device that includes a substrate comprising silicon material. The device also includes a gate structure overlaying a first surface region of the substrate. The device further includes a cavity region positioned within the substrate and adjacent to the first surface region of substrate. The cavity region has a tip region and a bottom region. The tip region includes a first angled sidewall extending directly below a portion of the first surface region. The first angled sidewall is characterized by a lattice plane of (1 1 1). The bottom region has a second angled sidewall positioned directly adjacent to a bottom surface of the cavity region.

According to another embodiment, the present invention provides a semiconductor device that includes a substrate comprising silicon material. The device also includes a gate structure overlaying a first surface region of the substrate. The device further includes a cavity region positioned within the substrate and adjacent to the first surface region of substrate. The cavity region includes a tip region and a bottom region. The tip region includes a first angled sidewall extending directly below a portion of the first surface region. The first angled sidewall is characterized by a lattice plane of (1 1 1). The bottom region has a second angled sidewall positioned directly adjacent to a bottom surface of the cavity region.

According to another embodiment, the present invention provides a method for fabricating a semiconductor device. The method includes providing a substrate that consists essentially of silicon material. The method also includes defining a first gate region and a second gate region on a surface of the substrate. The method further includes performing ion implantation on the first gate region and the second gate region to form a first doped region and a second doped region. The method also includes forming a first gate structure overlaying the first doped region. The method includes forming a second gate structure overlaying the second dope region. The method includes performing a first directional etching process using a first etchant to form a shallow trench characterized by a first height between a cavity region defined between the first gate structure and the second gate structure. The method includes forming a first offset spacer on a first gate sidewall. The first offset spacer is characterized by a first predefined width. A portion of the first offset spacer is positioned within the shallow trench. The method also includes forming a second offset spacer on a second gate sidewall. The second offset spacer is characterized by a second predefined width. A portion of the second offset spacer is positioned within the shallow trench. The method includes performing a second directional etching process between the first offset spacer and the second offset spacer into the cavity region. The method also includes removing the first offset spacer and the second offset spacer. The method also includes performing a wet etching process using at least a second etchant for a shaped cavity. The shaped cavity includes two tip regions interfacing with the substrate and a bottom region. The bottom region is characterized by a second height.

While the above is a full description of the specific embodiments, various modifications, alternative constructions and equivalents may be used. Therefore, the above description and illustrations should not be taken as limiting the scope of the present invention which is defined by the appended claims.

1. A semiconductor device comprising:
a substrate comprising silicon material;
a gate structure overlaying a first surface region of the substrate, wherein the gate structure comprises a hard mask layer arranged next to a spacer;
a cavity region positioned within the substrate and adjacent to the first surface region of substrate, the cavity region comprising a tip region and a bottom region, the tip region comprising a first angled sidewall extending directly below a portion of the first surface region, the first angled sidewall being characterized by the lattice plane of (1 1 1), the bottom region including a second angled sidewall positioned directly adjacent to a bottom surface of the cavity region, wherein the bottom surface is substantially flat; and
a filling material comprising silicon and germanium material positioned at least partially within the cavity region.

2. (canceled)

3. The device of claim 1 wherein the gate structure comprises an LDD layer.

4. The device of claim 1 wherein the substrate comprises a dope region positioned below the gate structure.

5. The device of claim 1 wherein the substrate comprises an n-well positioned below the gate structure.

6. The device of claim 1 wherein the substrate comprises a p-well positioned below the gate structure.

7. The device of claim 1 wherein the tip region is characterized by a first height and the bottom region is characterized by a second height, a ratio between the first height and the second height being approximately 1:1 to 1:2.

8. A semiconductor device comprising:
a substrate comprising silicon material;
a gate structure overlaying a first surface region of the substrate, wherein the gate structure comprises a hard mask layer arranged next to a spacer;
a cavity region positioned within the substrate and adjacent to the first surface region of substrate, the cavity region comprising a tip region and a bottom region, the tip region comprising a first angled sidewall extending directly below a portion of the first surface region, the first angled sidewall being characterized by lattice plane of (1 1 1), the bottom region including a second angled sidewall positioned directly adjacent to a bottom surface of the cavity region, wherein the bottom surface is substantially flat; and
a filling material comprising silicon carbide material positioned at least partially within the cavity region.

9. The device of claim 8 wherein the first tip region is characterized by a first height and the bottom region is characterized by a second height, a ratio between the first height and the second height being approximately 1:1 to 1:2.

10. The device of claim 8 wherein the filling material further comprises silicon germanium material.

11. The device of claim 8 wherein the gate structure comprises polysilicon material.

12. A method for fabricating a semiconductor device, the method comprising:
providing a substrate, the substrate consisting essentially of silicon material;
defining a first gate region and a second gate region on a surface of the substrate;
performing ion implantation on the first gate region and the second gate region to form a first doped region and a second doped region;
forming a first gate structure overlaying the first doped region;
forming a second gate structure overlaying the second dope region;
performing a first directional etching process using a first etchant to form a shallow trench characterized by a first height between a cavity region defined between the first gate structure and the second gate structure;
forming a first offset spacer on a first gate sidewall, the first offset spacer being characterized by a first predefined width, a portion of the first offset spacer being positioned within the shallow trench;
forming a second offset spacer on a second gate sidewall, the second offset spacer being characterized by a second predefined width, a portion of the second offset spacer being positioned within the shallow trench;
performing a second directional etching process between the first offset spacer and the second offset spacer into the cavity region;
removing the first offset spacer and the second offset spacer; and
performing a wet etching process using at least a second etchant for a shaped cavity, the shaped cavity comprising two tip regions interfacing with the substrate and a bottom region, the bottom region being characterized by a second height.

13. The method of claim 12 further comprising filling the shaped cavity with a silicon germanium material.

14. The method of claim 12 further comprising filling the shaped cavity with a silicon carbide material.

15. The method of claim 12 further comprising depositing a polysilicon material over the first gate region to form a part of the first gate structure.

16. The method of claim 12 further comprising depositing a GOX material over the first gate region to form a part of the first gate structure.

17. The method of claim 12 wherein the first etchant comprises one or more gaseous species in plasma form.

18. The method of claim 12 wherein the second etchant comprises a tetramethylammonium hydroxide material.

19. The method of claim 12 wherein the first offset spacer comprises silicon nitride material (SiN).

20. The method of claim 12 wherein a ratio between the first height and the second height is approximately 1:1 to 1:2.
